(19) United States
(12) Patent Application Publication
(10) Pub. No.: US 2003/0023933 A1
(43) Pub. Date: Jan. 30, 2003

(54) End-to-end disk data checksumming

(75) Inventor: William L. Duncan, Berthoud, CO (US)

Correspondence Address: David W. Victor, KONRAD RAYNES & VICTOR LLP, Suite 210, 315 S. Beverly Drive, Beverly Hills, CA, 90212, US

(73) Assignee: Sun Microsystems, Inc.

(21) Appl. No.: 09/917,315

(22) Filed: Jul. 27, 2001

(51) Int. Cl. G06F 11/10; H03M 13/00

(52) U.S. Cl. 714/807

(57) ABSTRACT

Provided is a method, system, and an article of manufacture for implementing a checksumming technique to a device driver to detect silent data corruption during read requests. A storage device is reformatted to create larger data blocks where a checksum can be stored with the data. A checksum is added during a write request, and calculated and compared during a read request. If an error was detected during retrieval, an error message is generated. However, if no error is detected, the checksum is removed before returning the data blocks to the application program.

### BACKGROUND OF THE INVENTION

1. Field of the Invention

The present invention relates to a method, system, and an article of manufacture for implementing disk data checksumming.

2. Description of the Related Art

A host or server system may concurrently execute multiple application programs that generate Input/Output (I/O) requests that are transmitted to a host bus adaptor providing a link to a storage device. The storage device may be comprised of multiple disks, such as the case with a Direct Access Storage Device (DASD), Just a Bunch of Disks (JBOD), a Redundant Array of Independent Disks (RAID), etc. In such devices, a priority for each application is retaining data integrity as data is transferred from the storage device to the host or server system. However, in today's environment where thousands of disks can exist in a storage device, hardware failures are bound to happen sooner or later. Besides disk errors, transport errors can be created by the SCSI cables, host bus adaptor card, device drivers, etc. Often such errors can go undetected, allowing corrupt data to propagate.

Undetected data corruption is often known as Silent Data Corruption (“SDC”). SDC occurs when an application program asks for data from the I/O subsystem (i.e. a disk read), and the data returned to that application is stale, altered or lost without being detected or corrected. Stale Data is data that was written at an earlier time and is incorrectly returned in place of the more recent (lost) data. Altered Data is data that is present but corrupt or changed and no longer correctly represents the original data. Finally, Lost Data is data that is lost and no longer available. Such errors are unavoidable in today's technology, but a larger problem is when such errors go undetected. In critical applications, the results of undetected errors can be catastrophic.

Thus, there is a need in the art to provide an improved technique for handling I/O requests for different applications executing within a host to detect silent data corruption.

### SUMMARY OF THE PREFERRED EMBODIMENTS

Provided is a method, system, and an article of manufacture for implementing an error detection scheme to read/write requests generated by an application program to a storage device. The driver program receives a write request from the application program to write data blocks at a first size to target data blocks in the storage device having a second size, wherein the second size is smaller than the first size. A checksum is generated by the driver program and associated with each data block in the write request. The data block with the checksum is transmitted by the driver program and stored in the target data blocks of the storage device.

Still further, in retrieving data from a requested location during a read request, the stored data blocks with the checksum are retrieved. The checksum associated with each retrieved data block is then calculated by the driver program. A determination is made by the driver program whether an error occurred during the storage or retrieval process by comparing the calculated checksum and the checksum stored at the requested location. If an error was detected, an error message is generated and the data is not returned. However, if no error is detected, the checksum is removed by the driver program before returning the data blocks to the application program.

In still further implementations, a checksumming flag is checked to determine whether the checksum should be generated on the write request and whether the checksum should be calculated and compared on a the read request.

In still further implementations, the checksum is seeded with the logical disk block number of the targeted disk block.

### BRIEF DESCRIPTION OF THE DRAWINGS

Referring now to the drawings in which like reference numbers represent corresponding parts throughout:

FIG. 1 is a block diagram illustrating a computing environment in which certain aspects of the invention are implemented;

FIG. 2 illustrates a block diagram of the device driver used to process checksumming in accordance with implementations of the invention;

FIGS. 3 and 4 illustrate logic implemented in a device driver program to execute checksumming to the I/O requests in accordance with implementations of the invention; and

FIG. 5 illustrates logic implemented in the host system to initialize the storage device for checksumming in accordance with implementations of the invention.

### DETAILED DESCRIPTION OF THE PREFERRED EMBODIMENTS

Checksumming is used in network protocols, where each transmitted message is accompanied by a checksum code generated from the bits in the message. For instance, many checksum algorithms perform an XOR of the bits in the message to generate the checksum value. The receiving station then applies the same checksum, e.g. XOR to the message and checks to make sure that the accompanying numerical value is the same as the checksum code in the transmission. Similarly, the checksum is used in the current implementation as an error-detection scheme to determine whether silent data corruption has occurred in retrieving the data from a storage device. However, implementing end-to-end checksumming in a host system from the application level to the storage device has not been attempted since control of both the hardware (i.e. the storage device) and the software (i.e. the operating system's disk drivers) has not been available. Moreover, unlike network protocols, implementing checksums in a host system environment creates additional challenges since different requirements are demanded from the host system and the storage device than simply communicating between two devices. Design considerations include impact on system time, impact on system resources (i.e. CPU time, memory, disk capacity, etc.), other functions to be performed by the host and storage device, etc. Although checksums have been used within hard disk drives, existing checksum features within disk drives have limitations. For instance, checksums implemented within the storage device alone cannot detect silent data corruption which occurs between the storage device and the host applications. Therefore, the present invention discloses an improved method, system, and program to perform end-to-end checksumming in a disk storage system.

In the following description, reference is made to the accompanying drawings which form a part hereof and which illustrate several embodiments of the present invention. It is understood that other embodiments may be utilized and structural and operational changes may be made without departing from the scope of the present invention.

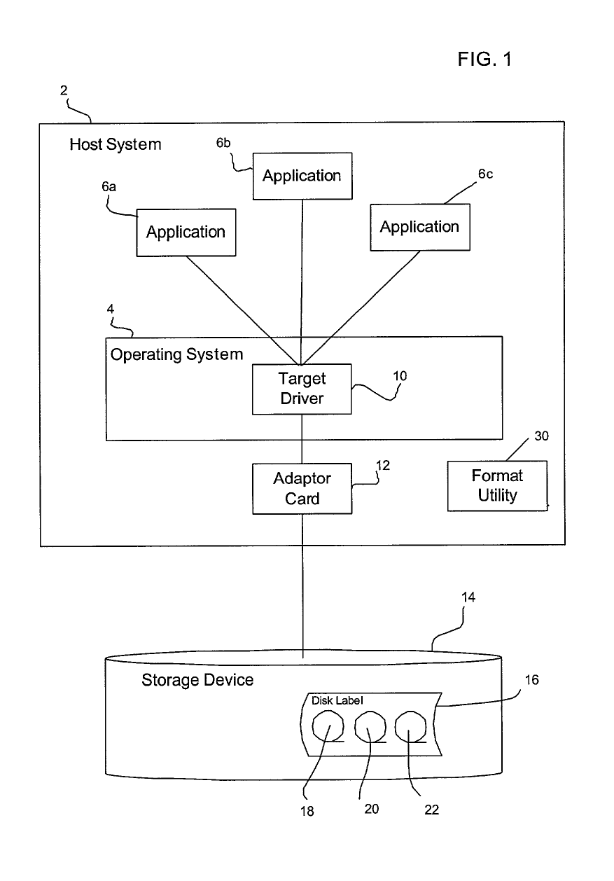

FIG. 1 illustrates a computing environment in which preferred embodiments are implemented. A host system 2 includes an operating system 4 and is capable of executing multiple application programs 6a, b, c. (Although multiple applications can be executed on the host 2, only three application programs 6a, b, c are shown for illustration purposes.) The application programs 6a, b, c generate Input/Output (I/O) requests to a storage device 14, where the data files used by the application programs 6a, b, c are stored and recalled. The host system 2 further includes a target driver 10 and a host bus adaptor (HBA) 12. In current implementations, to coordinate the I/O process, all I/O requests are transferred from the application programs 6a, b, c to the target driver 10. The target driver 10 then communicates the I/O requests to a host bus adaptor (HBA) 12 to transfer the I/O request to a storage device 14 in a manner known in the art.

The host 2 may comprise any computational device capable of executing multiple application programs and transferring data to the storage device 14, including a server class machine, a mainframe, desktop computer, laptop computer, hand held computer, telephony device, etc. The operating system 4 may comprise any operating system known in the art capable of concurrently executing multiple application programs 6a, b, c and concurrently generating I/O requests. The storage device 14 may comprise any storage device known in the art, such as a Direct Access Storage Device (DASD), Just a Bunch of Disks (JBOD), a Redundant Array of Independent Disks (RAID), tape library, optical library, etc. The target driver 10 further includes device driver code to perform device driver related operations to the storage device 14. In the described implementations, the target driver 10 may be implemented as a software program that executes within the host 2.

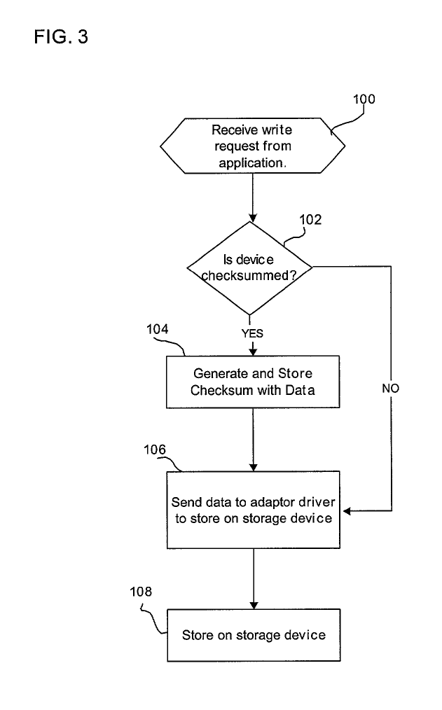

Contained in the storage device 14 is a disk label 16 on the first data block of the storage device 14. This existing data structure already contains fields that describe the physical disk, such as “volume name”, “number of sectors, tracks, and cylinders”. If the storage device 14 is comprised of multiple storage units, e.g. disk drives, the disk label would be in the first block of each storage unit within the storage device 14. This label 16 further includes the VTOC (Volume Table of Contents), which contains a list of disk “slices” (or partitions). In the described implementations, the disk label 16 is modified for checksumming by adding the following to the disk label 16: (1) checksummed “on” flag 18; (2) checksumming algorithm version 20; and (3) checksumming meta-data version 22. The checksummed “on” flag 18 is used to quickly identify whether the storage device 14 is checksum enabled. Whether the checksum is enabled will be discussed below in conjunction with FIGS. 3-5. A checksumming algorithm version 20 is added to identify what version of the checksumming algorithm is being used on the storage device 14. Having a version number associated with the disk label 16 will make switching between one algorithm and another much simpler to perform. Lastly, checksumming meta data version 22, which describes how and when and by whom a particular set of data was collected, and how the data is formatted, is also used to independently make switching between one algorithm and another much simpler to perform.

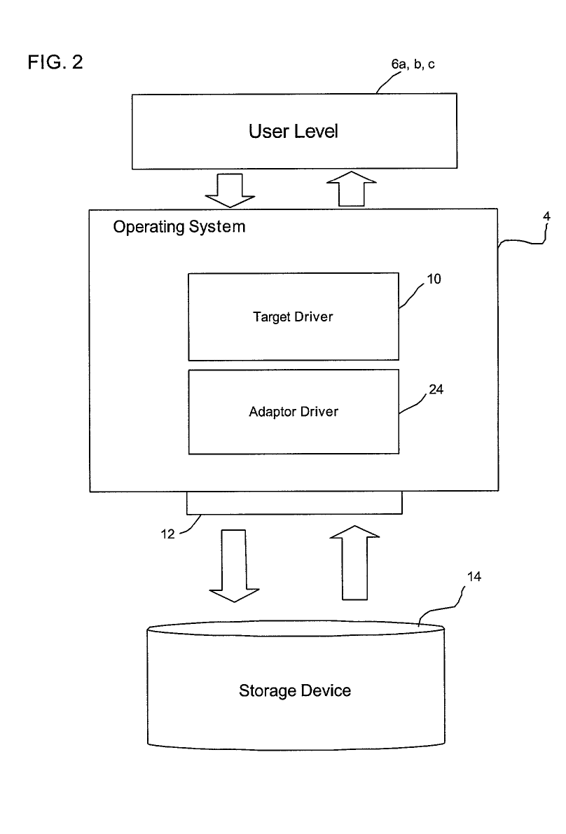

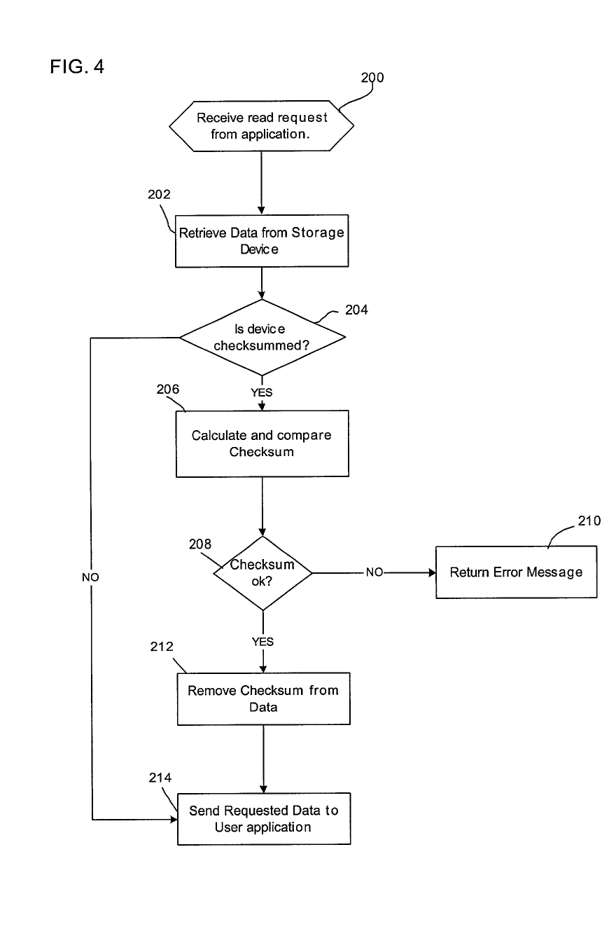

FIG. 2 illustrates a block diagram of the target driver 10 used to process checksumming in accordance with implementations of the invention. Within the operating system 4, a target driver 10 receives the I/O request and determines which blocks should be accessed to read/write the data used by the applications 6a, b, c. The target driver 10 will then determine which blocks in the storage device 14 will hold/currently hold the data subject to the I/O request. In addition, the target driver 10 adds a checksum to the data blocks on the write function and subtracts the checksum on the read function, which will be explained in greater detail with regards to FIGS. 3 and 4. Subsequently, an adaptor driver 24 communicates with the HBA card 12 to give read/write instructions to the HBA card 12 for the specifically targeted disk block. Other layers exist in the I/O subsystem but are not pertinent to the checksumming feature in the present implementations. The checksum feature can be performed at either the target driver 10 or adaptor driver 24 level. However, implementing the checksum routine at the target driver 10 level is advantageous because the checksum covers more of the I/O path (i.e. more “end-to-end”), interacts with all types of adaptor drivers, operates without any hardware support, and operates directly on the user data sent from the application programs 6a, b, c.

In the present implementation, the checksum is comprised of a 32-bit Exclusive-Or (XOR) checksum, where the checksum is seeded with the logical disk block number of the targeted disk block. In the present implementation, the checksum for each data block is kept with the data in the same data block rather than keeping the checksum information in a separate location on the storage device 14. Maintaining the checksum with the data keeps the number of logical I/Os and the number of physical I/Os the same, avoids hidden sectors which are hidden or protected in the storage device 14, and avoids the need to wait for the checksums to be loaded into a cache before being able to protect the data (important during reboot processes).

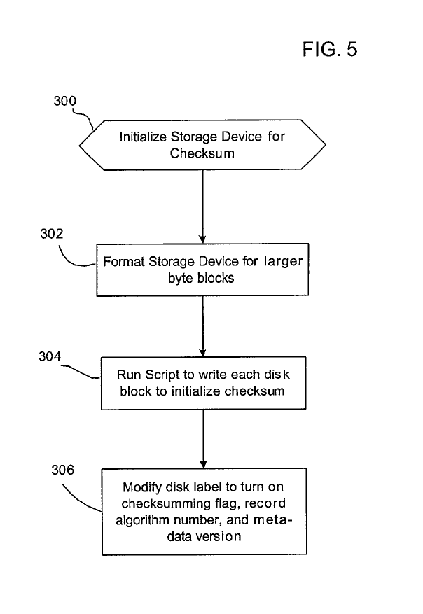

Presently, application programs 6a, b, c typically process data in blocks of 512 bytes, and thus, the standard storage device 14 is initialized to store 512-byte data blocks. However, in order to add 32 bits of checksum (4 bytes), the standard 512-byte disk block will now require 516 bytes of storage capacity (i.e. 512-bytes of data +4 bytes of checksum) in order to keep the checksum and the data in the same data block. Thus, one implementation formats disks 14 to use a larger physical block size of 528-bytes. Using 528-bytes rather than 516-byte disk blocks reserves twelve (12) bytes for future use in case a different checksumming algorithm is later used that requires more space, including an error correction scheme, etc. Thus, sixteen bytes of protection is provided so that future changes to the checksum can be made without having to reformat the storage device 14 again. The initialization process of the storage device 14 will be discussed in greater detail with respect to FIG. 5.

FIGS. 3 and 4 illustrate logic implemented in the target driver program 10 to execute checksumming of the I/O requests in accordance with implementations of the invention. With respect to FIG. 3, control begins at block 100 when the target driver 10 receives a write request from one application 6a, b, c. As is common for most device drivers 10, the write request is processed in the target driver 10 in data blocks of 512 bytes. Before target driver 10 performs the write function, the target driver 10 first determines (at block 102) whether checksumming is enabled for this storage device 14 by checking the checksumming flag 18 on the disk label 16. If the storage device 14 does not have checksumming enabled, a determination is made by the target driver 10 that the checksum algorithm cannot be performed and the write request is simply sent to the adaptor driver 24 (at block 106) without using the checksum algorithm. However, if the storage device 14 has checksumming enabled, the target driver 10 (at block 104) allocates memory and seeds a checksum with the logical disk block number of the open disk block using standard Cyclic Redundancy Check (CRC) procedures known in the art. Seed or Seeding is a term of art used to describe the process of adding information to the beginning of a data block, in which the present embodiments seed the checksum with the block number. The checksum is then stored with the write data to increase the data size of the write data block up to 528-bytes. At block 106, the data block with the checksum is then sent to the adaptor driver 24, which communicates directly with the HBA card 12. The adaptor driver 24 instructs the adaptor card 12 to write the data block with the checksum at the location determined by the target driver 10 in a manner known in the art (at block 108).

FIG. 4 illustrates logic implemented in the target driver 10 to read data from the storage device 14 when the checksum feature has been incorporated. With respect to FIG. 4, control begins at block 200 when the target driver 10 receives a read request from one application 6a, b, c. Upon identifying the read request, the target driver 10 locates where the data blocks are stored on the storage device 14. The target adaptor 10 then sends the location of the requested data blocks to the adaptor driver 24, and the adaptor driver 24 recalls the data blocks from the storage device 14 through the HBA card 12 in a manner known in the art (at block 202). At block 204, the recalled data blocks are returned to the target driver 10 and the target driver 10 determines whether the returned data block has incorporated the checksum feature. The target driver 204 checks the checksumming flag on the disk label. Thus, if checksumming is not enabled for this device, the target driver 10 will understand that the checksum feature was not added during the write function, and the checksum algorithm will not be used. The returned data blocks will simply be sent to the application program 6a, b, or c in a manner known in the art. However, if checksum is enabled, the target driver 10 will use the checksum algorithm. Thus, the same target driver 10 is flexible enough to be used in a storage device 14 using 512-byte disk blocks or 528-byte disk blocks.

At block 206, the target driver 10 calculates the checksum associated with the data block using CRC techniques. At block 208, a simple compare function is performed between the retrieved checksum and the requested location of the data block. The compare operator will return a value of “true” only if both values are the same. If a “false” value is returned the target driver 10 will be able to determine that an incorrect data block was returned or that the data was corrupt. At block 210, an error message is sent to the application program 6a, b, or c, notifying that an error was detected during the read request. If a “true” value is returned, the target driver 10 (at block 212) will then strip away the checksum from the read data to decrease the data size of the write data block down to 512-bytes from 528-bytes. At block 212, the data blocks are sent to the application program 6a, b, or c in the format that the application program 6a, b, or c can read (i.e. 512-byte disk blocks).

FIG. 5 illustrates logic implemented in the host system to initialize the storage device 14 for checksumming in accordance with implementations of the invention. In the described implementation, the initialization code is stored as a format utility 30 within the storage device 14, but alternatively, the code can be stored in a separate storage unit or run from a UNIX shell prompt manually from the host system 2 or any other system connected to the storage device 14. Control begins at block 300 when the storage device 14 receives an initialization command. At block 302, a Format command is used to reformat the storage device 14 to create data blocks of 528-byte blocks throughout the storage device 14. After formatting, at block 304, a shell script uses the dd(1) command to write each disk block with zeroes to initialize the checksums for each data block in the storage device 14. In addition, at block 306, the disk label 16 is modified to turn on the checksumming flag 18, and to record the algorithm version 20 and meta-data version 22 in the disk label 16. Once the initialization process is complete, the disk driver 10 can perform checksumming for all I/O operations used with the storage device 14.

One advantage of including the checksum program at the host or driver level, versus within the disk drive or storage device enclosure, is the ability to detect silent data corruption that occurs between the disk drive and the host. As stated before, silent data corruption may result from transport errors occurring in the SCSI cables, host bus card adaptor, device drivers, etc. By placing the checksum routine at the host or driver level, silent data corruption occurring upstream from the disk drive is detected. In addition, another advantage to locating the checksum routine at the host or drive level is the ability to implement the checksum independent of the hardware. No additional hardware is required to perform the checksum function. Instead, a software update can be performed to an existing host system to install an updated device driver containing the checksum program or update the checksum program itself. Furthermore, keeping the checksum function at the host or driver level allows the checksum to remain functionally transparent to users, operating without affecting existing applications on the host system or requiring updates or modifications to host system applications.

### Additional Implementation Details

The preferred embodiments may be implemented as a method, apparatus or article of manufacture using standard programming and/or engineering techniques to produce software, firmware, hardware, or any combination thereof. The term “article of manufacture” as used herein refers to code or logic implemented in hardware logic (e.g., an integrated circuit chip, Field Programmable Gate Array (FPGA), Application Specific Integrated Circuit (ASIC), etc.) or a computer readable medium (e.g., magnetic storage medium (e.g., hard disk drives, floppy disks, tape, etc.), optical storage (CD-ROMs, optical disks, etc.), volatile and non-volatile memory devices (e.g., EEPROMs, ROMs, PROMs, RAMs, DRAMs, SRAMs, firmware, programmable logic, etc.). Code in the computer readable medium is accessed and executed by a processor. The code in which preferred embodiments are implemented may further be accessible through a transmission media or from a file server over a network. In such cases, the article of manufacture in which the code is implemented may comprise a transmission media, such as a network transmission line, wireless transmission media, signals propagating through space, radio waves, infrared signals, etc. Of course, those skilled in the art will recognize that many modifications may be made to this configuration without departing from the scope of the present invention, and that the article of manufacture may comprise any information bearing medium known in the art.

The described implementations provided a technique for managing the flow of I/Os to a device driver for a storage device. The type of storage device does not matter as long as it supports 528-byte blocks.

In the described implementations, a 32-bit XOR algorithm was used for checksumming. Alternatively, other algorithms can be used for checksumming which will compare the checksum of the retrieved data with the requested data, such as such as the Fletcher32-p algorithm. In addition, the checksum was described with a maximum of eight bytes of information. Alternatively, the storage device can be reformatted to any other disk block size to increase or decrease the disk block sizes to accommodate a different checksum sizes. For example, a 520-byte block size maybe used instead of a 528-byte data block. In addition, in the preferred embodiments, the version number of the checksumming algorithm was kept with the disk label. Alternatively, one byte of version information (i.e. 8 bits reserved to keep track of the checksum algorithm version number) can be stored in the checksum area of the disk block (i.e. use one byte from the spare four bytes of space in the checksum area). In addition, in the preferred embodiments, the determination of whether the checksum feature was enabled on the storage device was made by checking the checksumming flag on the disk label. In alternative embodiments, a determination of whether the checksum feature is enabled can be performed by checking the size of the data blocks in the storage device without the use of a checksumming flag.

In the described implementations, the checksumming feature was performed by the target driver. Alternatively, a checksumming driver could just be layered on top of any of the current I/O driver stacks or implemented in another layer of the I/O subsystem. In addition, the code of the target driver 10 is described as including the device driver code for the storage device. Alternatively, the target driver may be a separate program or routine called by the device driver.

The preferred logic of FIGS. 3, 4, and 5 described specific operations occurring in a particular order. In alternative embodiments, certain of the logic operations may be performed in a different order, modified or removed and still implement preferred embodiments of the present invention. Morever, steps may be added to the above described logic and still conform to the preferred embodiments.

Therefore, the foregoing description of the preferred embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto. The above specification, examples and data provide a complete description of the manufacture and use of the composition of the invention. Since many embodiments of the invention can be made without departing from the spirit and scope of the invention, the invention resides in the claims hereinafter appended.

What is claimed is:

1. A method for implementing an error detection scheme to read/write requests generated by an application program in a host system to a storage device, comprising:
receiving with a driver program in the host system a write request from the application program to write data blocks at a first size to target data blocks in the storage device, wherein the target data blocks in the storage device have a second size, wherein the second size is larger than the first size;
generating with the driver program a checksum for each data block in the write request;
transmitting with the driver program the data block with the checksum to the storage device, wherein the storage device stores the data blocks and checksums in the target data blocks.

2. The method of claim 1, wherein the driver program further performs:
receiving data blocks and the checksum for each data block from the storage device in response to a read request;
calculating a new checksum for each retrieved data block;
determining, for each retrieved data block, whether an error occurred by comparing the new checksum with the checksum retrieved from the storage device with the data block;
for each data block, if the error is determined, then generating an error message; and
for each data block, if no error is determined, then returning the data block to the application program without the checksum stored with the data block in the storage device.

3. The method of claim 1, wherein the driver program is included within a target driver.

4. The method of claim 1, wherein the checksum is comprised of a 32-bit Exclusive-Or logic.

5. The method of claim 1, wherein the step of generating the checksum further comprises:
seeding the checksum with a logical block number of the target data block in the storage device that stores the data block.

6. The method of claim 1, further comprising:
initializing the storage device by creating data blocks at the second size;
running a script program to write initial data in each data block of the storage device; and
generating a checksumming flag to indicate that the storage device is checksum enabled.

7. The method of claim 1, wherein the second size is 528-bytes and the first size is 512-bytes.

8. The method of claim 1, further comprising:
checking a checksumming flag to determine whether the checksum should be generated.

9. The method of claim 2, the device program further comprising:
checking a checksumming flag to determine whether the checksum should be calculated and compared; and
if the checksumming flag indicates that the storage device is checksum enabled, checking the data structures.

10. The method of claim 1, wherein a target driver transmits the write request to an adaptor driver to communicate to an output device.

11. The method of claim 1, wherein the storage device is a member of a set of storage devices comprising a Direct Access Storage Device (DASD), Just a Bunch of Disks (JBOD), a Redundant Array of Independent Disks (RAID), a tape library and an optical library.

12. A system for implementing an error detection scheme to read/write requests generated by an application program to a storage device, comprising:
means for receiving with a driver program a write request from the application program to write data blocks at a first size to target data blocks in the storage device, wherein the target data blocks in the storage device have a second size, wherein the second size is larger than the first size;
means for generating with the driver program a checksum for each data block in the write request;
means for transmitting with the driver program the data block with the checksum to the storage device, wherein the storage device stores the data blocks and checksums in the target data blocks.

13. The system of claim 12, wherein the driver program further comprises:
means for receiving data blocks and the checksum for each data block from the storage device in response to a read request;
means for calculating a new checksum for each retrieved data block;
means for determining, for each retrieved data block, whether an error occurred by comparing the new checksum with the checksum retrieved from the storage device with the data block;
for each data block, if the error is determined, then a means for generating an error message; and
for each data block, if no error is determined, then a means for returning the data block to the application program without the checksum stored with the data block in the storage device.

14. The system of claim 12, wherein the driver program is included within a target driver.

15. The system of claim 12, wherein the checksum is comprised of a 32-bit Exclusive-Or logic.

16. The system of claim 12, wherein the means for generating the checksum further comprises:
means for seeding the checksum with a logical block number of the target data block in the storage device that stores the data block.

17. The system of claim 12, further comprising:
means for initializing the storage device by creating data blocks at the second size;
means for running a script program to write initial data in each data block of the storage device; and
means for generating a checksumming flag to indicate that the storage device is checksum enabled

18. The system of claim 12, wherein the second size is 528-bytes and the first size is 512-bytes.

19. The system of claim 12, further comprising:
means for checking a checksumming flag to determine whether the checksum should be generated.

20. The system of claim 13, the device program further comprising:
means for checking a checksumming flag to determine whether the checksum should be calculated and compared; and
if the checksumming flag indicates that the storage device is checksum enabled, means for checking the data structures.

21. The system of claim 12, wherein a target driver transmits the write request to an adaptor driver to communicate to an output device.

22. The system of claim 12, wherein the storage device is a member of a set of storage devices comprising a Direct Access Storage Device (DASD), Just a Bunch of Disks (JBOD), a Redundant Array of Independent Disks (RAID), a tape library and an optical library.

23. An article of manufacture for implementing an error detection scheme to read/write requests generated by an application program to a storage device, comprising a computer usable media including at least one computer program embedded therein that is capable or causing at least one computer to perform:
receiving with a driver program a write request from the application program to write data blocks at a first size to target data blocks in the storage device, wherein the target data blocks in the storage device have a second size wherein the second size is larger than the first size;
generating with the driver program a checksum for each data block in the write request;
transmitting with the driver program the data block with the checksum to the storage device, wherein the storage device stores the data blocks and checksums in the target data blocks.

24. The article of manufacture of claim 23, wherein the driver program further performs:
receiving data blocks and the checksum for each data block from the storage device in response to a read request;
calculating a new checksum for each retrieved data block;
determining, for each retrieved data block, whether an error occurred by comparing the new checksum with the checksum retrieved from the storage device with the data block;
for each data block, if the error is determined, then generating an error message; and
for each data block, if no error is determined, then returning the data block to the application program without the checksum stored with the data block in the storage device.

25. The article of manufacture of claim 23, wherein the driver program is included within a target driver.

26. The article of manufacture of claim 23, wherein the checksum is comprised of a 32-bit Exclusive-Or logic.

27. The article of manufacture of claim 23, wherein the step of generating the checksum further comprises:
seeding the checksum with a logical block number of the target data block in the storage device that stores the data block.

28. The article of manufacture of claim 23, further performing:
initializing the storage device by creating data blocks at the second size;
running a script program to write initial data in each data block of the storage device; and
generating a checksumming flag to indicate that the storage device is checksum enabled.

29. The article of manufacture of claim 23, wherein the second size is 528 bytes and the first size is 512-bytes.

30. The article of manufacture of claim 23, further performing:
checking a checksumming flag to determine whether the checksum should be generated.

31. The article of manufacture of claim 24, the device program further performing:
checking a checksumming flag to determine whether the checksum should be calculated and compared; and
if the checksumming flag indicates that the storage device is checksum enabled, data structures are also checked.

32. The article of manufacture of claim 23, wherein a target driver transmits the write request to an adaptor driver to communicate to an output device.

33. The article of manufacture of claim 23, wherein the storage device is a member of a set of storage devices comprising a Direct Access Storage Device (DASD), Just a Bunch of Disks (JBOD), a Redundant Array of Independent Disks (RAID), a tape library and an optical library.
